(19) United States
(12) Patent Application Publication
(10) Pub. No.: US 2024/0213125 A1
(43) Pub. Date: Jun. 27, 2024

(54) EDGE-STRUCTURED LEADFRAME FOR EMBEDDED DIE PACKAGING OF POWER SEMICONDUCTOR DEVICES

(71) Applicant: GaN Systems Inc., Kanata (CA)

(72) Inventor: Abhinandan DIXIT, Kanata (CA)

(21) Appl. No.: 18/085,684

(22) Filed: Dec. 21, 2022

(51) Int. Cl. H01L 23/495; H01L 23/29; H01L 23/31

(52) U.S. Cl. CPC H01L 23/49565; H01L 23/295; H01L 23/3107

(57) ABSTRACT

Embedded die packaging for high voltage, high temperature operation of power semiconductor switching devices is disclosed, wherein a power semiconductor die is mounted on a leadframe and embedded in laminated body comprising a layer stack of a plurality of dielectric layers and electrically conductive layers. Electrical connections between contact pads of the power semiconductor die and external contact pads of the package comprise conductive vias extending through the dielectric layers. Edges of the leadframe are structured to provide vertical and lateral interlocking of the leadframe with surrounding dielectric, e.g. by providing a leadframe having a laterally scalloped and vertically undercut edge structure. Edges of the leadframe may be beveled.

### CROSS-REFERENCE TO RELATED APPLICATION(S)

This application is related to U.S. provisional patent application No. 63/350,562, filed Jun. 9, 2022, entitled “Dual Side-Cooled Embedded Die Packaging for Power Semiconductor Devices”, which is incorporated herein by reference in its entirety.

This application is related to U.S. patent application Ser. No. 17/728,220 filed Apr. 25, 2022, entitled “Embedded Die Packaging for Power Semiconductor Devices” which is a continuation of U.S. patent application Ser. No. 16/928,305, filed Jul. 14, 2020, of the same title; all these patent applications are incorporated herein by reference in their entirety.

### TECHNICAL FIELD

This invention relates to embedded die packaging for power semiconductor devices and more particularly to leadframe embedded die packaging for power semiconductor devices, such as GaN semiconductor power transistors for high-voltage, high-current applications.

### BACKGROUND

The above-referenced related patent applications disclose examples of embedded die packaging for power semiconductor devices based on a laminated package body comprising a plurality of dielectric layers and electrically conductive metal layers, in which internal electrical connections between a power semiconductor die and conductive metal layers are made with conductive vias and/or microvias extending through the dielectric layers.

GaN power transistors, such as GaN HEMTs, provide for high current, high voltage operation combined with high switching frequency. For some power applications, GaN power devices and systems offers advantages over silicon technology using Si IGBTs and diodes and SiC power transistors and diodes. For example, power switching systems comprising lateral GaN transistors provide higher efficiency switching, with lower losses, and smaller form factor than comparable systems based on silicon or SiC technology. To benefit from the inherent performance characteristics of lateral GaN transistors, important design considerations include, e.g.: device layout (topology), low inductance interconnect and packaging, and effective thermal management. Lateral GaN power transistors for high current operation at 100V and 650V operation are currently available from GaN Systems Inc. based on Island Technology® that provides a large gate width W_{g}, low on-resistance, Rₒₙ, and high current capability per unit active area of the device.

Embedded die packaging solutions that offer low inductance interconnections, and low thermal impedance, are disclosed, for example, in U.S. patent application Ser. No. 16/928,305, filed Jul. 14, 2020, entitled “Embedded Die Packaging for Power Semiconductor Devices”, references cited therein, and non-patent publications relating to GaNPx® embedded die packaging. U.S. Ser. No. 16/928,305 discloses embedded die packaging for power semiconductor devices which comprises a laminated structure built up from layers of dielectric materials and conductive metal layers. This type of laminated embedded die packaging provides low parasitic inductance in a compact (i.e. small form factor) package for high voltage, high current GaN e-HEMTs.

GaN power switching devices, such as those mentioned above offered by GaN Systems Inc., which are embedded in a GaNPX type laminated package of small size, e.g. 7 mm×5 mm and 0.5 mm thick, are capable of operation at voltages in a range from 100V to 650V, for switching currents of tens or hundreds of Amps. Operating temperatures may reach or exceed 100 C. For small size dies having a high current capability per unit active area, and smaller package sizes, e.g. chip-scale packaging, package components are therefore subjected to higher electric fields and higher operating temperatures than for low voltage, lower power switching devices.

Embedded die packages may be required to pass standard moisture sensitivity level (MLS) testing to meet performance requirements for a particular industry application. If moisture is trapped in the package, trapped moisture may expand during thermal processing, e.g. during solder reflow for surface mounting. The expansion of trapped moisture, to create water vapour, can result in interfacial delamination between metal and dielectric resin/prepreg layers of embedded die packages and/or internal cracking that may extend to the surface, leading to electrical failure. For some applications, it may be sufficient for components to pass MSL Level 3 (MSL3) testing, e.g. 3 reflow cycles between 0° C. and 260° C. in 60% ambient humidity. For more demanding applications, such as for automotive components, MSL Level 1 (MSL1) qualification requires that parts pass testing for more extreme or harsh conditions, e.g. 3 reflow cycles between 0° C. and 260° C. in 100% ambient humidity, without pre-baking; and parts are also required to pass temperature cycling (TC) over an extended range of temperatures, e.g. from −55° C. to 175° C., over 1000 cycles. After these tests, the embedded die packages undergo imaging to check for delamination or cracking.

Mismatch of thermal coefficient of expansion (CTE) between the conductive metal layers and dielectric layers of a laminated embedded die package may lead to interlayer stresses, and potential delamination or cracking, during thermal cycling. For laminated embedded die packages where the dielectric material comprises a glass fiber reinforced epoxy resin composition, glass fibers may be stressed during the lamination process.

There is a need for improved or alternative embedded die packaging, particularly for high voltage/high current power switching semiconductor devices, such as GaN HEMTs, e.g., to provide improved reliability to meet more stringent testing and qualification, e.g. for automotive applications.

### SUMMARY OF INVENTION

The present invention seeks to provides improved or alternative embedded die packaging for power semiconductor devices, and particularly for high voltage/high current wide-bandgap semiconductor power switching devices, e.g. GaN HEMTs and SiC power MOSFETS, which mitigate or circumvent at least one of the above-mentioned issues.

One aspect provides an embedded die package comprising a laminated body and a die comprising a power semiconductor device, the die being embedded within the laminated body, the laminated body comprising a stack of a plurality of dielectric layers and a plurality of electrically conductive layers, wherein the die is mounted on a leadframe, and edges of the leadframe are structured to provide vertical and lateral interlocking of the leadframe with surrounding dielectric. For example, edges of the leadframe have a scalloped and undercut edge structure. Electrical connections between contact pads of the power semiconductor device and external contact pads of the package comprise conductive vias extending through the dielectric layers.

For example, an embedded die package comprises a laminated body and a die comprising a power semiconductor device, the die being embedded within the laminated body, wherein:
the laminated body comprises comprising a layer stack of a plurality of dielectric layers and electrically conductive layers;
a first electrically conductive layer comprising a leadframe defining contact pads;
the die being mounted on the leadframe;
electrical connections between contact pads of the die, contact pads the leadframe and any other electrically conductive layers comprise electrically conductive vias extending through the dielectric layers;
wherein edges of the leadframe are structured provide vertical and lateral interlocking of the leadframe and surrounding dielectric layers.

For example, the leadframe has a scalloped and undercut edge structure, and edges of the leadframe may be beveled. The leadframe may comprise lateral scallops and a vertical undercut. The leadframe may be part-etched, e.g. half-etched to define a recess for mounting of the die.

For example, for embedded die packages wherein the dielectric layers comprise a glass fiber filled epoxy composite resin, the lateral scallops are configured for stress relief of glass fibers within the resin.

For example, an embedded die package comprises a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a thermal pad, the thermal contact area of the die being in thermal contact with the thermal pad of the leadframe;
a dielectric core comprising at least a first dielectric build-up layer embedding the die and at least top and side surfaces of the leadframe;
a second conductive layer;
the second conductive layer being patterned to define interconnect areas;
the interconnect areas of the second conductive layer being connected by electrically conductive vias to respective electrical contact areas of the power semiconductor device and electrical contact areas of the leadframe; and
wherein edges of the leadframe are structured provide vertical and lateral interlocking of the leadframe and the at least first dielectric buildup layer embedding the at least top and side surfaces the leadframe.

For example, an embedded die package comprises a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a primary thermal pad, the thermal contact area of the die being in thermal contact with the primary thermal pad of the leadframe;
a first dielectric build-up layer embedding the die and the leadframe;
a second conductive layer on the first dielectric build-up layer;
the second conductive layer being patterned to define interconnect areas;
the interconnect areas of the second conductive layer being connected by electrically conductive vias to respective electrical contact areas of the power semiconductor device and electrical contact areas of the leadframe; and
a second dielectric build-up layer on the second conductive layer;
a third conductive layer on the second dielectric build-up layer defining external electrical contact areas;
the external electrical contact areas of the third conductive layer being connected by electrically conductive vias to respective electrical internconnect areas of the second conductive layer; and
wherein edges of the leadframe are structured to provide lateral and vertical interlocking of at least the first dielectric buildup layer embedding the leadframe.

For example, an embedded die package further comprises a fourth conductive layer underlying the first conductive layer and separated therefrom by another dielectric build-up layer, the fourth conductive layer forming an external thermal pad which is in thermal contact with the primary thermal pad of the first conductive layer. Thermally conductive vias may provide said thermal contact between the first thermal pad and the external thermal pad.

For example, an embedded die package comprises a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a core comprising at least one dielectric layer which embeds the die;
a first dielectric build-up layer on a first side of the core;
a first conductive layer on the first dielectric build-up layer;
the first conductive layer comprising a leadframe, the leadframe being patterned to define a primary thermal pad and electrical interconnect areas, the thermal contact area of the die being in thermal contact with the primary thermal pad;
a second dielectric build-up layer on a second side of the core,
a second conductive layer on the second dielectric build-up layer,
the second conductive layer being patterned to define electrical contact areas, the interconnect areas of the first conductive layer being connected by electrically conductive vias to respective electrical contact areas of the power semiconductor device and respective electrical contact areas of the first conductive layer;
a third dielectric build-up layer on the first conductive layer;
a third conductive layer on the third dielectric build up layer;
the third conductive layer being patterned to define a secondary thermal pad;
wherein the primary and secondary thermal pads providing for dual-side cooling; and
wherein edges of the leadframe are structured to provide lateral and vertical interlocking of at least the first dielectric buildup layer embedding the leadframe.

Thermal vias provide for said thermal contact between the first thermal pad and the thermal contact on the back-side of the die. A fourth conductive layer may be provided underlying the first conductive layer and separated therefrom by another dielectric build-up layer, the fourth conductive layer forming an external thermal pad which is in thermal contact with the first thermal pad of the first conductive layer, thermally conductive vias are provide said thermal contact between the first thermal pad and the external thermal pad.

Embedded die packaging of example embodiments for high voltage, high temperature operation of power semiconductor switching devices are disclosed. For example, when the power semiconductor device comprises a lateral semiconductor power transistor, said electrical contact areas of the power semiconductor device comprise electrical contact areas for a source, drain and gate of the lateral power transistor on the bottom-side of the package. Vias comprising electrically conductive and thermally conductive material provide electrical connection and thermal contact between the first thermal pad and the source.

In some embodiments, the laminated body is based on a bottom-side-cooled layup that provides the primary thermal pad and electrical connections for the power semiconductor device on the first side (bottom-side) of the package and wherein the secondary thermal pad is provided on the opposite side (top-side) of the package.

In some embodiments the laminated body is based on a top-side cooled layup that provides the primary thermal pad on the first side (top-side) of the package and wherein the secondary thermal pad and electrical connections for the power semiconductor device are provided on the opposite side (bottom-side) of the package for dual-side cooling.

Thus, embedded die packages of example embodiments provide for improvements in embedded die packaging for power semiconductor switching devices comprising leadframes. Embedded die packages of example embodiments provide for packaging of high voltage and high current power switching devices, e.g. comprising GaN HEMTs, SiC MOSFETs which operate at elevated temperatures, e.g. for improved device performance and reliability.

### BRIEF DESCRIPTION OF THE DRAWINGS

FIG. 1A (Prior Art) shows 3D rendering of an example of an embedded die package comprising a E-mode lateral GaN HEMT device structure embedded in a laminated dielectric body with a bottom-side thermal pad;

FIGS. 1B and 1C show schematic top-side and bottom-side views of the embedded die package shown in FIG. 1A;

FIG. 2A (Prior Art) shows 3D rendering of an example of an embedded die package comprising a E-mode lateral GaN HEMT device structure embedded in a laminated dielectric body with a top-side thermal pad;

FIGS. 2B and 2C show schematic top-side and bottom-side views of the embedded die package shown in FIG. 2A.

FIG. 3A shows a 3D rendering of top-side and bottom-side views a dual-side cooled embedded die package of example embodiments;

FIGS. 3B and 3C show schematic top-side and bottom-side views of the embedded die package shown in FIG. 3A;

FIG. 4 shows a schematic top plan view of a semiconductor die comprising an E-mode lateral GaN HEMT of an example embodiment to illustrate a device topology with large area source and drain contact areas and dual gate contact areas;

FIG. 5 shows a plan view of the bottom side of a dual-side cooled embedded die package of a first example embodiment;

FIG. 6A shows a schematic cross-sectional view through plane A-A of FIG. 5 to illustrate the laminated multilayer structure of the dual-side cooled embedded die package of the first example embodiment;

FIG. 6B shows a schematic cross-sectional view through plane B-B of FIG. 5 to illustrate the laminated multilayer structure of the dual-side cooled embedded die package of the first example embodiment;

FIG. 7 shows a schematic cross-sectional view a top-cooled embedded die package with an edge-structured leadframe of a second example embodiment;

FIG. 8 shows a schematic 3D rendering to illustrate detail of a part of a metal leadframe having a structured edge comprising scallops and undercut for interlocking of the metal leadframe with a dielectric body of an embedded die package;

FIG. 9 shows a schematic cross-section view to illustrate detail of the part of a metal leadframe of FIG. 8 having a structured edge with an undercut, and wherein the leadframe is half-etched to form a recess for mounting of a power semiconductor die;

FIG. 10 shows a schematic plan view of part of a metal leadframe having a structured edge to illustrate a first example pattern of scallops;

FIG. 11 shows a schematic cross-sectional view of part of a metal leadframe having a structured edge to illustrate an example undercut profile;

FIG. 12 shows a schematic plan view of part of a metal leadframe having a structured edge to illustrate a second example pattern of scallops;

FIG. 13 shows a schematic cross-sectional view of part of a metal leadframe having a structured edge to illustrate another example undercut profile;

FIG. 14A shows a plan view of a leadframe for an embedded die package of a third example embodiment, wherein the leadframe has a structured edge;

FIG. 14B shows a schematic cross-sectional view through plane A-A of FIG. 14A;

FIG. 15 shows a plan view of the leadframe of FIG. 14A, with a power semiconductor die mounted on the leadframe;

FIG. 16 shows a plan view to illustrate patterning of metal 2 to define internal source, drain and gate metal interconnect;

FIG. 17 shows a plan view to illustrate patterning of metal 3 to define external contact pads for the source, drain and gate;

FIG. 18 shows a plan view to illustrate patterning of metal 4 to define thermal pad for top-side cooling;

FIG. 19 shows a schematic overlay of metal 1 (leadframe), metal 2, metal 3 and metal 4 showing patterning of electrically conductive vias and thermally conductive vias for electrical and thermal interconnections between metal 1, metal 2, metal 3, and metal 4;

FIG. 20 shows a schematic cross-sectional view of a layup of a leadframe and prepreg layers prior to lamination;

FIG. 21 shows a schematic cross-sectional view of a layup of a leadframe and prepreg layers after lamination; and

FIG. 22 shows an electron micrograph of a cross-sectional of an embedded die package to illustrate deformation of glass fibers when prepreg is pressed into cavities around the leadframe.

The foregoing and other features, aspects and advantages of the present invention will become more apparent from the following detailed description, taken in conjunction with the accompanying drawings, of example embodiments of the invention, which description is by way of example only.

### DETAILED DESCRIPTION

For background information on packaging of power semiconductor devices, packaging solutions that offer low inductance interconnections are disclosed, for example, in the Applicant's earlier filed patent documents: U.S. patent application Ser. No. 15/027,012, filed Apr. 15, 2015, now U.S. Pat. No. 9,659,854, entitled “Embedded Packaging for Devices and Systems Comprising Lateral GaN Power Transistors”; U.S. patent application Ser. No. 15/064,750, filed Mar. 9, 2016, now U.S. Pat. No. 9,589,868, entitled “Packaging Solutions for Devices and Systems Comprising Lateral GaN Power Transistors”; U.S. patent application Ser. No. 15/064,955, filed Mar. 9, 2016, now U.S. Pat. No. 9,589,869, entitled “Packaging Solutions for Devices and Systems Comprising Lateral GaN Power Transistors”; and U.S. patent application Ser. No. 15/197,861, filed Jun. 30, 2016, now U.S. Pat. No. 9,824,949, entitled “Packaging Solutions for Devices and Systems Comprising Lateral GaN Power Transistors”.

As described herein, “embedded die packaging” refers to package structures in which a power semiconductor die, e.g. comprising a lateral GaN HEMT, is embedded in a dielectric package body, e.g.: a dielectric polymer resin composition, such as a glass fiber epoxy composite, such as FR4 type materials. For example, as described in U.S. patent application Ser. No. 16/928,305, entitled “Embedded Die Packaging for Power Semiconductor Devices” filed Jul. 14, 2020 (now U.S. Pat. No. 11,342,248), the body of the package is a laminated structure built-up from layers of dielectric and layers of conductive metal. This type of laminated embedded die packaging provides low parasitic inductance in a compact (i.e. small form factor) package for high voltage, high current GaN HEMTs. For example, a 100V, 90 A GaN e-HEMT (GS61008T) may be provided in a top-side cooled laminated package which is about 7 mm×4 mm, and 0.54 mm thick; a 650V, 60 A GaN e-HEMT (GS66516T) may be provided in a laminated package which is 9 mm×7.6 mm and 0.54 mm thick.

The dielectric polymer resin composition forming laminated embedded die packaging may include laminate sheets and layers of composite material referred to as prepreg, which is a substrate material, such as woven or non-woven glass-fiber cloth, which is pre-impregnated with one or more polymer materials, such as a dielectric epoxy composition. The dielectric epoxy composition may comprise an epoxy resin, curing agents, additives, such as fire retardants, and fillers and other substances to modify properties of the resulting composite material. One or more pre-cured epoxy laminate sheets and/or uncured prepreg layers are cut to form a cavity for the semiconductor die, and sandwiched between other uncured prepreg layers, i.e. assembled as a layer stack (which may be referred to as a layup), and the layers are then bonded together in a press, e.g. in a curing process using heat and pressure, to form a laminated dielectric body of the package in which the semiconductor die is embedded.

For power semiconductor devices, a typical embedded die package comprises low inductance electrical interconnect layers and conductive vias, e.g. formed from plated copper, and a thermal pad, also formed from plated copper. The outer layers of an embedded package comprise an isolation layer which is a coating of a material that provides an electrically insulating and protective outer covering over the underlying dielectric and conductive layers, e.g. the outer dielectric layer covers underlying layers including copper source, drain and gate interconnect traces, and openings are provided in the outer dielectric layer for the external source, drain and gate contact areas, and for the thermal pad.

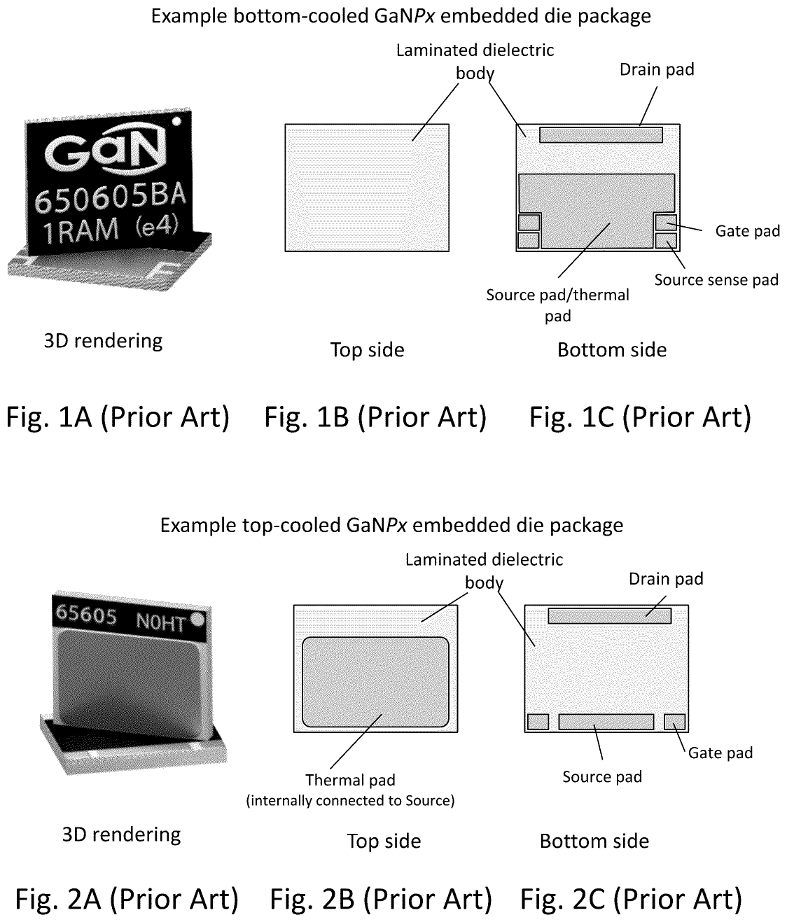

Examples of embedded die packaging device structures comprising a laminated dielectric body containing a lateral GaN power transistor are shown schematically in FIGS. 1A, 1B and 1C and FIGS. 2A, 2B and 2C. FIG. 1A shows top-side and bottom-side 3D views of a first example of a package comprising an embedded GaN-on-Si die comprising a 650V lateral GaN e-HEMT. As shown in FIG. 1B, the top-side of the package comprises an exposed layer of dielectric of the laminated dielectric body, and as shown in FIG. 1C, the bottom side of the package comprises a source pad/thermal pad, a drain pad, and source sense and gate contact pads. This type of package, where the electrical contact pads and thermal pad are provided on the same side of the package is referred to as a bottom-side cooled embedded package, or B-type embedded die package. FIG. 2A shows top-side and bottom-side 3D views of another example of a package comprising an embedded GaN-on-Si die comprising a lateral GaN e-HEMT. As shown in FIG. 2B, the top-side of the package comprises a thermal pad, which is internally connected to source. As shown in FIG. 2C, the source, drain and gate contact pads are provided on a bottom-side of the package. This type of package, where the electrical contact pads are provided on one side of the package and the thermal pad is provided on the opposite side, is referred to as a top-side cooled embedded package, or T-type embedded die package.

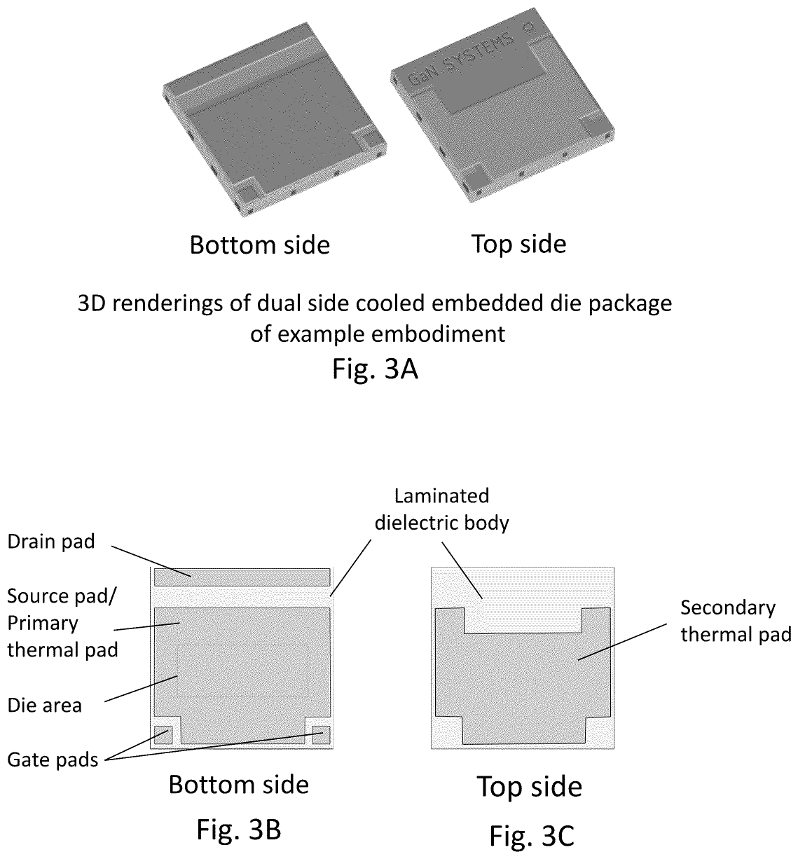

FIG. 3A show views of 3D renderings of the bottom side and top side of an embedded die package of example embodiments comprising a laminated dielectric body and primary and secondary thermal pads for dual-side cooling. FIG. 3B shows a schematic plan view of the bottom side, comprising a source pad, which is also the primary thermal pad, a drain pad and gate pads. FIG. 3C shows a schematic plan view of the top side, comprising the secondary thermal pad.

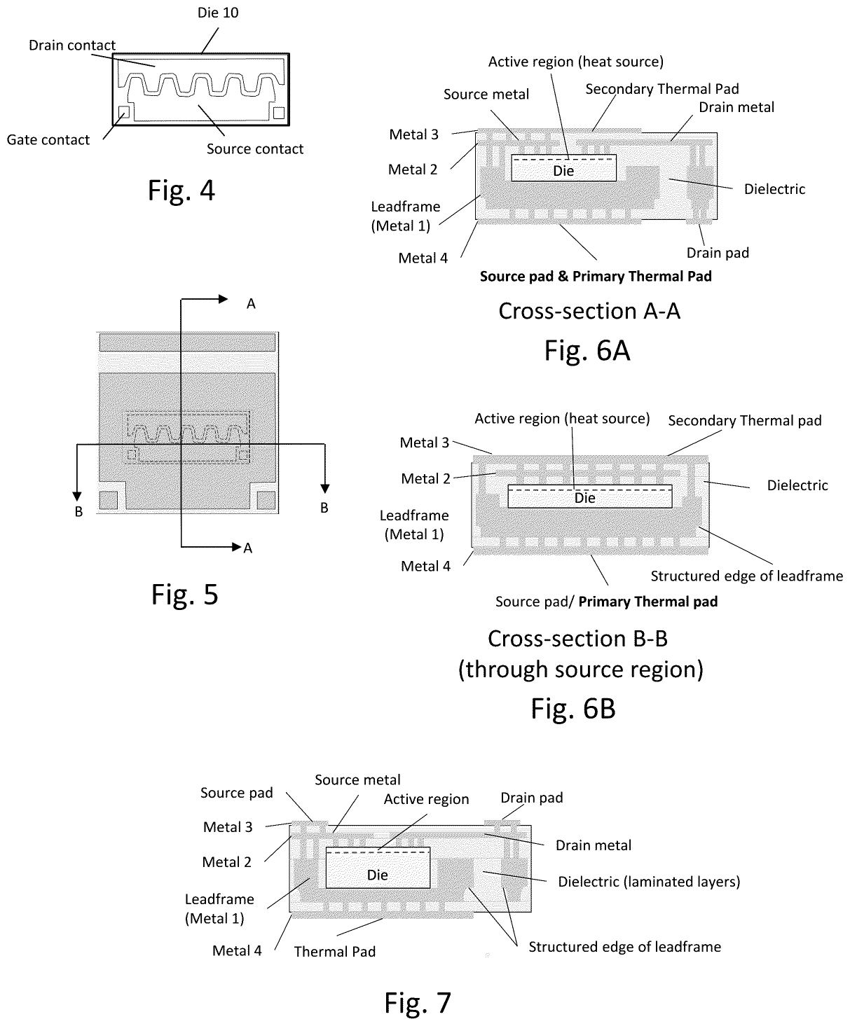

FIG. 4 shows a schematic top plan view of an example power semiconductor die comprising a lateral GaN power transistor, wherein the die comprises a thick copper redistribution layer (RDL), which defines large area source and drain contact areas (source pad and drain pad) and dual gate contact areas (gate pads), on the front-side (active side) of the die.

FIG. 5 shows a schematic plan view of an embedded die package of a first example embodiment. The internal position of the embedded die is shown in dotted outline. As an example, the outline of the package may be square or rectangular, e.g. having external dimensions of ˜10 mm×˜10 mm or ˜5 mm×˜10 mm. FIGS. 6A and 6B show schematic cross-sectional views through sections A-A and B-B respectively of FIG. 5 to illustrate the internal layer structure. The embedded die package comprises a laminated dielectric body comprising an epoxy composition fabricated from laminations comprising several epoxy laminate and prepreg layers (light green) and conductive copper layers (copper color). In this embodiment, there are four conductive metal layers (Metal 1, Metal 2, Metal 3 and Metal 4). The die is mounted on a leadframe (Metal 1). The active region of the die (front or top-side of the die) is facing upwards in this view, and the back-side of the die is attached in thermal contact with the leadframe. Metal 2 is patterned to define source and drain connections (source metal and drain metal), and gate connections (not shown in this view). Metal 4 defines a source pad which is also a primary thermal pad. Metal 3 defines a secondary thermal pad. Electrical and thermal interconnections between metal layers 1, 2, 3 and 4 are provided by electrically conductive vias and thermally conductive vias. For example, these components may comprise low inductance conductive copper interconnects comprising copper filled vias or copper filled micro-vias. Copper filled thermal vias provide thermal contact between the leadframe and the primary thermal pad on the bottom side of the package. Plated copper layers provide the external source, drain and gate pads on a bottom-side of the package, and the secondary thermal pad on the top-side of the package. External surfaces of the source, drain and gate pads and thermal pads may be provided with a plating of e.g. nickel and gold, to facilitate surface mounting, e.g. by soldering, or other processing.

A schematic cross-sectional view a top-cooled embedded die package with an edge-structured leadframe of a second example embodiment is shown in FIG. 7, comprising a laminated dielectric body comprising an epoxy composition fabricated from laminations comprising several epoxy laminate and prepreg layers (light green) and conductive copper layers (copper color). In this embodiment, there are four conductive metal layers (Metal 1, Metal 2, Metal 3 and Metal 4). The die is mounted on a leadframe (Metal 1). The active region of the die (front or top-side of the die) is facing upwards in this view, and the back-side of the die is attached in thermal contact with the leadframe. Metal 2 is patterned to define source and drain connections (source metal and drain metal), and gate connections (not shown in this view). Metal 4 defines a source pad which is also a thermal pad. Metal 3 defines external source, drain and gate pads. Electrical and thermal interconnections between metal layers 1, 2, 3 and 4 are provided by electrically conductive vias and thermally conductive vias. For example, these components may comprise low inductance conductive copper interconnects comprising copper filled vias or copper filled micro-vias. Copper filled thermal vias provide thermal contact between the leadframe and the thermal pad on the top-side of the package. Plated copper layers provide the external source, drain and gate pads on a bottom-side of the package. External surfaces of the source, drain and gate pads and thermal pads may be provided with a plating of e.g. nickel and gold, to facilitate surface mounting, e.g. by soldering, or other processing.

In FIG. 5, FIGS. 6A and 6B, and FIG. 7, it will be appreciated that layer thicknesses and lateral dimensions are shown schematically, and are not drawn to scale; the lateral patterning of shapes of the metal layers are shown as rectangular shapes, by way of example only. For example, in the plan view of FIG. 5, in practice, internal and external corners of the source, drain and gate contact areas may be 90 degrees as shown schematically, or radiused to avoid sharp corners.

To assist with adhesion of the package dielectric to the leadframe the surfaces of the lead frame are roughened, e.g. by surface etching, to promote adhesion of the package dielectric to the leadframe. For embedded die packages where there is only a single lamination or a few laminations, surface roughening of the leadframe may be sufficient to improve adhesion and reduce risk of delamination during thermal cycling for less harsh operating conditions. As illustrated schematically in FIG. 6A and FIG. 6B, and FIG. 7 edges of the lead frame a structured with an undercut to improve interlocking of the dielectric around the leadframe.

Embedded die packaging of power semiconductor devices for automotive applications is required to survive harsher conditions, e.g. to achieve a MSL1 rating. Power semiconductor switching devices for high-voltage and high-current operation for automotive applications may result in higher operational temperatures, e.g. ≥75 C or ≥100 C, and more extreme thermal cycling. A mismatch of coefficient of thermal expansion between conductive metal layers of the leadframe and the epoxy composite dielectric layers of an embedded die package may lead to cracking and delamination caused by thermal cycling. These effects tend to be exacerbated in multi-layer layups with three or more metal layers and dielectric layers. For glass fiber containing prepreg dielectric materials, the glass fibers may be stressed during pressing and curing for the lamination process. Contact points of the ends of glass fiber strands and the metal leadframe may be points of stress, from which cracking and/or delamination may be initiated. For example, for harsher conditions, e.g. automotive applications, embedded die packaging may be required to pass temperature cycling of 1000 cycles from −55° C. to 175° C. and to meet requirements for MSL1.

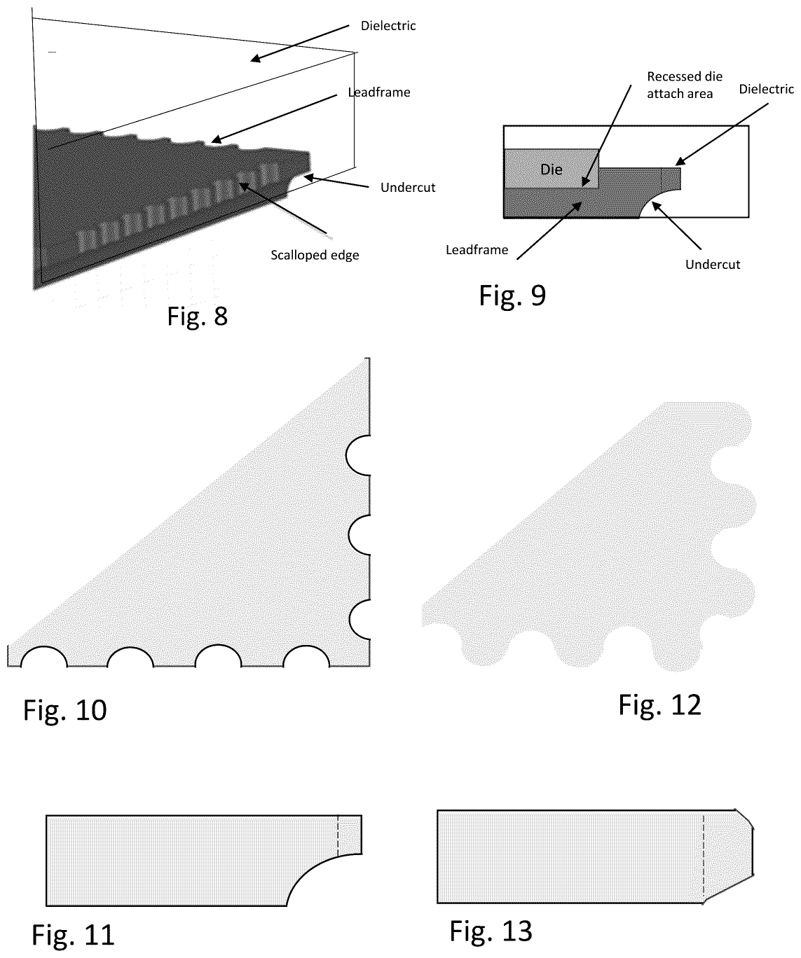

FIG. 8 shows a schematic 3D rendering to illustrate detail of a part of a metal leadframe having a structured edge comprising scallops and undercut for interlocking of the metal leadframe with a dielectric body of an embedded die package. FIG. 9 shows a schematic cross-section view to illustrate detail of the part of a metal leadframe of FIG. 8 having a structured edge with an undercut, and wherein the leadframe is half-etched to form a recessed die attach area for mounting of a power semiconductor die. The structured edge of the leadframe has both a lateral pattern and a vertical pattern to provide multi-directional or three-dimensional interlocking of the metal of the leadframe and the dielectric material of the package body. Surfaces of the leadframe may also be surface-roughened to promote adhesion of dielectric material.

FIG. 10 shows a schematic plan view of part of a metal leadframe having a structured edge to illustrate an example pattern of scallops to form a scalloped edge structure. FIG. 11 shows a schematic cross-sectional view of part of a metal leadframe having a structured edge to illustrate an example undercut profile.

FIG. 12 shows a schematic plan view of part of a metal leadframe having a structured edge to illustrate another example pattern of scallops with rounded edges. FIG. 13 shows a schematic cross-sectional view of part of a metal leadframe having a structured edge to illustrate another example undercut profile where the top edge and bottom edges are chamfered or bevelled.

FIGS. 14A, 14B, and FIGS. 15 to 19 show schematic views of the metal layers, Metal 1 (leadframe), Metal 2, Metal 3 and Metal 4 of a top-cooled embedded die package of a third example embodiment, e.g. based on a layup as illustrated schematically in FIG. 7. As shown schematically in FIG. 14A, Metal 1 provides a leadframe, which is patterned to provide a source pad and a drain pad. The leadframe has scalloped and undercut edges, e.g. as illustrated schematically in FIG. 10 and FIG. 11. The source pad is part-etched, e.g. half-etched, to form a recess for a die attach area, e.g. as shown in the schematic cross-sectional view in FIG. 14B

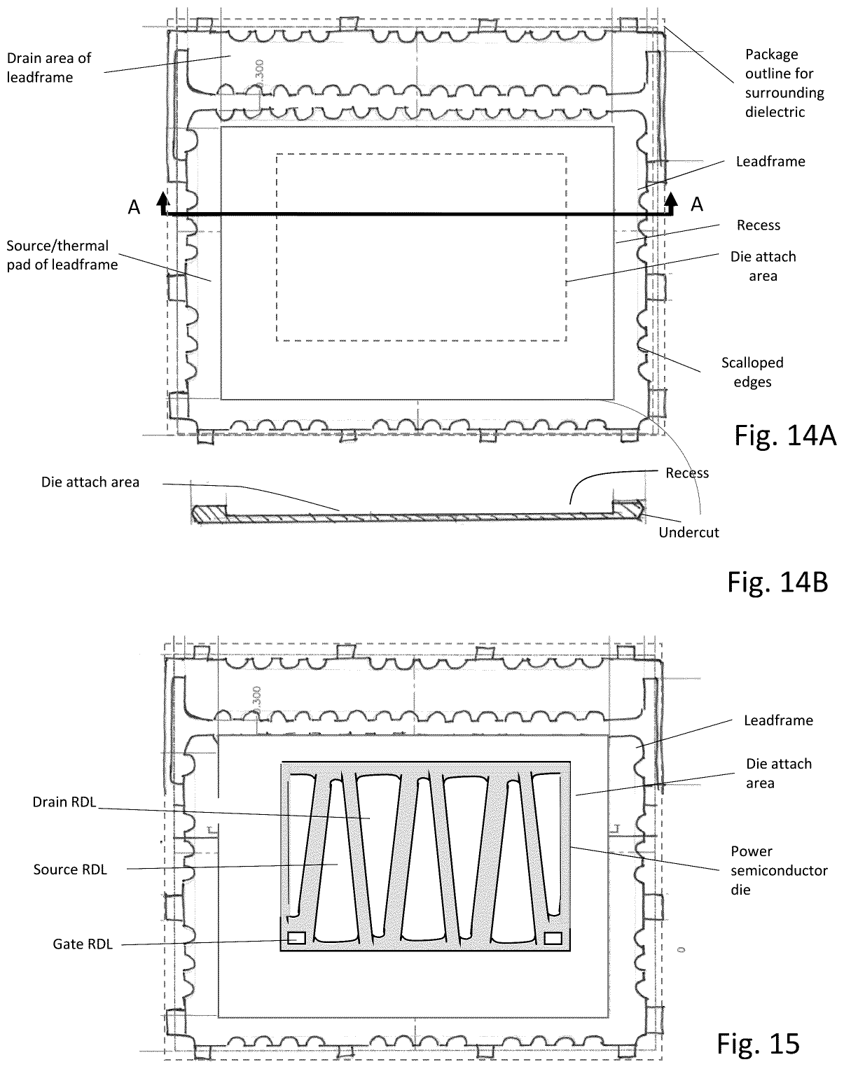

FIG. 15 shows a schematic view of a power semiconductor die mounted on the leadframe of FIG. 14A. The power semiconductor die is mounted on the die attach area, and the active side of the die comprises large area contacts for the drain (drain RDL) and source (source RDL), and gate contacts (gate RDL).

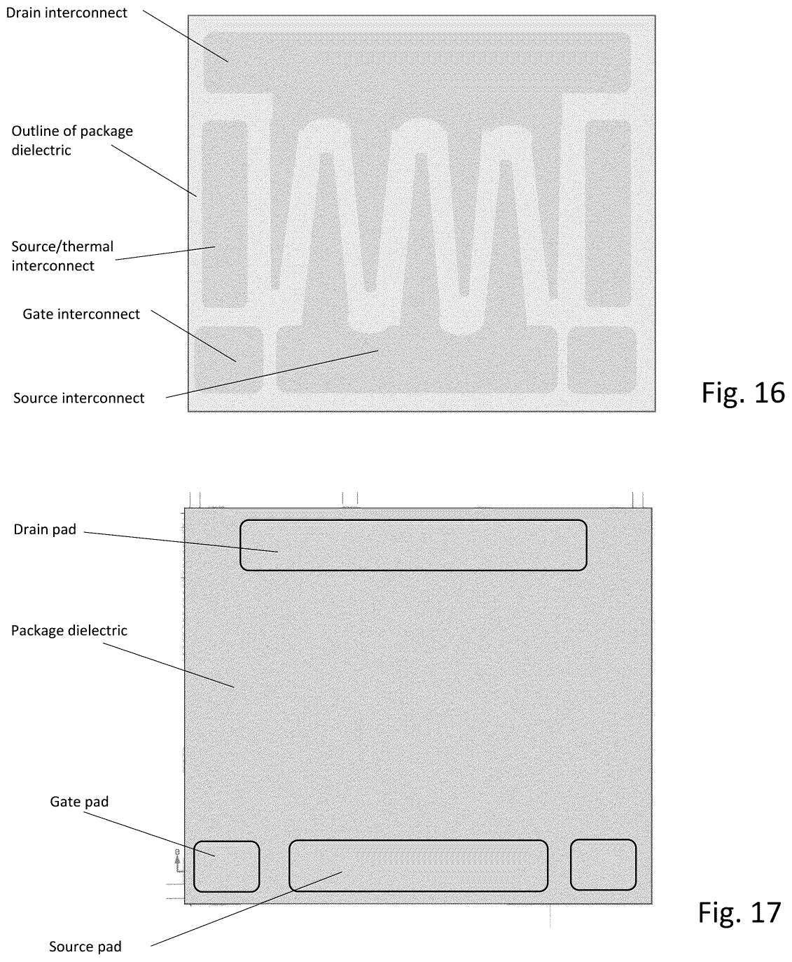

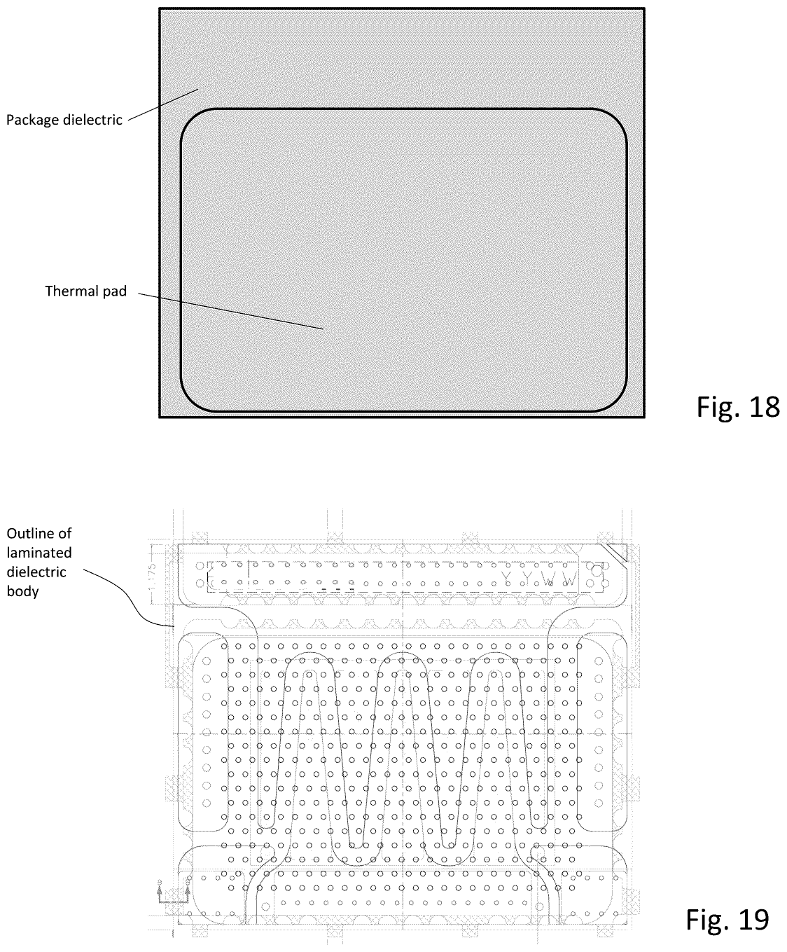

FIG. 16 shows the patterning of Metal 2, to define source interconnect, drain interconnect and gate interconnect areas which are interconnected by electrically conductive vias to respective source, drain and gate contacts on the active side of the die. FIG. 17 shows a schematic diagram to illustrate patterning of Metal 3, to define external source, drain and gate pads, which are interconnect by electrically conductive vias to the underlying interconnect areas. FIG. 18 shows a schematic diagram to illustrate patterning of Metal 4 to define the top thermal pad, which is in thermal contact, through thermal vias with the underside of the leadframe. FIG. 19 shows a schematic overlay of layers of Metals 1, 2, 3, and 4 and an example pattern of electrically conductive vias and thermally conductive vias, which electrically and thermally interconnect the metal layers

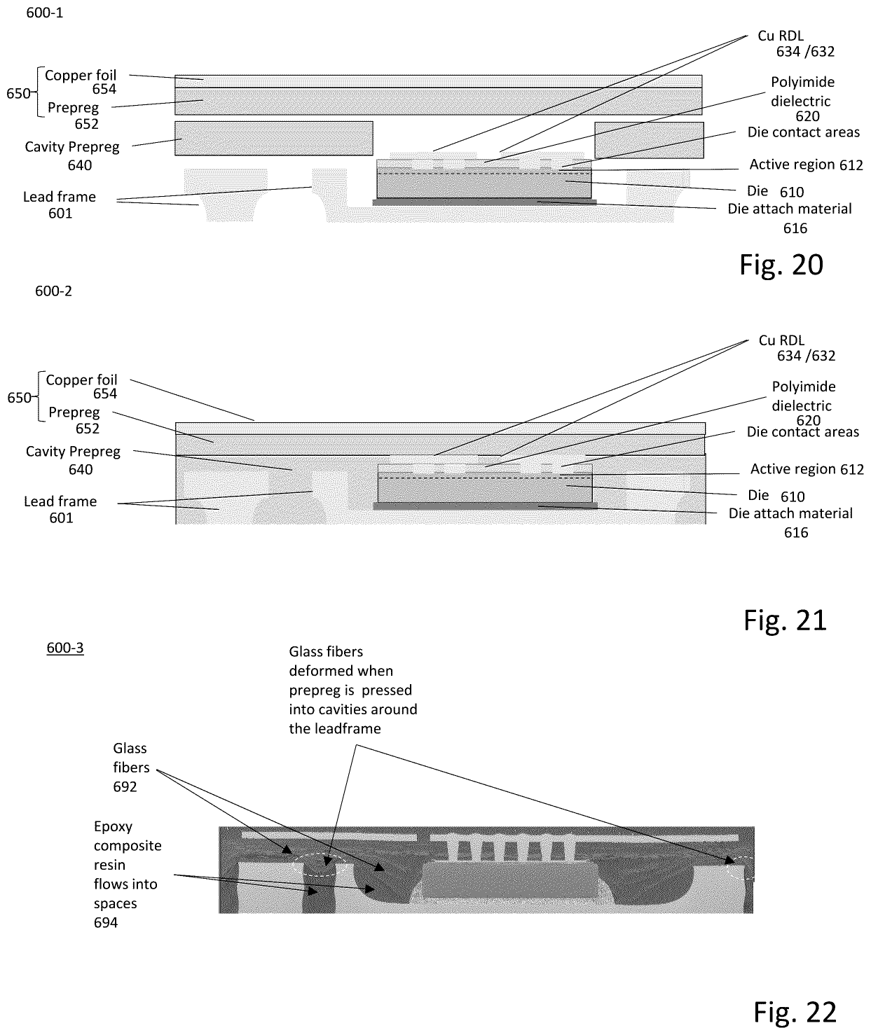

FIG. 20 shows a schematic cross-sectional view of a layup of a leadframe and dielectric layers comprising a cavity prepreg 640, e.g. comprising a glass fiber filled epoxy resin composite, and a cover prepreg 654, e.g. comprising a glass fiber filled epoxy resin composite layer 652 and a copper foil layer 654, prior to lamination. FIG. 21 shows a schematic cross-sectional view of a layup of a leadframe and prepreg layers after lamination. During lamination, the epoxy composite resin flows into cavities around the lead frame and embeds the die and the top and side surfaces of the leadframe 601. The undercut edges of the leadframe 601 provide vertical interlocking, which helps to anchor the leadframe within the dielectric layers. The scalloped edges of the leadframe provide lateral interlocking, and the scalloped edges also provide stress relief for the glass fibers of the dielectric layers. For example, as illustrated in the electron micrograph image of a cross-section of an embedded die package of a conventional structure, during lamination, the glass fibers are deformed when the cavity prepreg is pressed into cavities around the leadframe. For example, FIG. 22 shows an electron micrograph of a cross-sectional of an embedded die package to illustrate deformation of glass fibers when prepreg is pressed into cavities around the leadframe.

A scalloped edge provides some stress relief to the fibers around edges of the leadframe. A leadframe having a structured edge as described herein, provides for improved vertical and lateral interlocking of the leadframe within the laminated package body, and a scalloped edge, and optionally bevelled edges of the leadframe, also provide stress relief for glass fibers which are deformed during lamination. For embedded die packages for power semiconductors of example embodiments comprising layups that comprise multiple conductive layers, which may be referred to as 6-layer structures, or 0+2 and 1+2 layups, where there is greater stress on the leadframe, a leadframe having a structured edge comprising these features promotes adhesion between the leadframe and dielectric layers of the laminated body of the package, to improve package integrity, and enable embedded die packages that meet requirements for MLS 1 qualification, e.g. for automotive applications.

While embodiments of embedded die packaging for a power semiconductor device are described in detail with refer to a power semiconductor device comprising a GaN power transistor, a power semiconductor device may comprise a GaN diode. The power semiconductor device may comprise a plurality of GaN power transistors, a plurality GaN power diodes, a combination of at least one GaN power transistor and at least one power diode. For example, the die may comprise a power semiconductor device which comprises a plurality of GaN transistors configured as one of: a half-bridge, a full-bridge, and other switching topologies. The die may comprise other components, integrated with the power semiconductor device, e.g., one or more of driver circuitry, control circuitry, sensors, passive components, et al., The power semiconductor device may be co-packaged and interconnected with other components, such as a driver chip, embedded in the package.

Embedded die packages of exemplary embodiments are described herein, wherein the power semiconductor device comprises a GaN power transistor device, such as at least one high voltage, high current GaN HEMT, which is described as having first and second contact areas which are referred to as source and drain contact area, and a third contact area which is described at a gate contact area. Embedded die packing of these embodiments are also applicable for embedded die packaging of GaN power diodes, in which the first and second contact areas would be referred to as anode and cathode contact areas, instead of source and drain contact areas. For example, for power semiconductor devices comprising lateral GaN HEMTs and GaN power diodes rated for, e.g. 100V or 650V operation, and for currents in a range of e.g. 20 A to ≥100 A, dielectric regions between source and drain contact areas of GaN HEMTS, or between anode and cathode contact areas of power diodes, which are provided on a front-side of the die, are subject to significant electric fields during operation. Additional build-up dielectric layers isolating these power areas of the die provides for improved reliability.

It is contemplated that in other example embodiments of embedded die packaging wherein the laminated dielectric body (layup) comprises additional dielectric buildup layers isolating contact areas in regions subject to e.g. high electric fields, or thermal cycling, during operation may also be more generally applicable to other semiconductor devices, where higher reliability embedded die packaging is required, because external coatings of solder resist can then be eliminated.

For example, the power semiconductor device may comprise another type of power transistor, e.g. a SiC MOSFET or a Si IGBT, or another type of power diode. For example, the power semiconductor device may comprise at least one power transistor, at least one power diode, a combination of at least one power transistor and at least one power diode, fabricated using GaN technology or other III-Nitride technology, or Si technology or SiC technology or other Group IV semiconductor technology, or other semiconductor technology applicable to power semiconductor devices.

Examples of suitable dielectric materials for the core and build-up layers of the laminated package body are described in related patent applications cited herein. For example, the at least one dielectric layer of the core and said first, second and outer dielectric build-up layers comprise any one of: a glass-fiber reinforced resin composition; a glass-fiber reinforced epoxy resin composition; a dielectric resin build-up layer; a dielectric epoxy build-up layer; a build-up layer which is formed from an ABF (Ajinimoto Build-up Film); and a combination thereof. The dielectric build-up layer may be a vacuum laminated dielectric. For example, a vacuum laminated reinforced dielectric underlying the solder resist may be formed from an epoxy prepreg or a sheet of an epoxy resin composition comprising filler particles, known as a BUF (build-up film).

The laminated body may comprise a layer stack which is symmetric or asymmetric, and is configured with at least one of a top-side and a bottom side thermal pad. The core and dielectric build-up layers may comprise a dielectric epoxy composition having an FR4 epoxy composition, such as Panasonic R1577 or Hitachi E679 or other composition having similar electrical and mechanical characteristics. The dielectric build-up layers may comprise a BUF polymer composition such as Sekishi NX04H, N!07, NQ07X or NR10.

In exemplary embodiments, the conductive metallization layers of the embedded die packaging are described as comprising copper, e.g. plated copper. In other embodiments, any suitable metal, for example Cu, Al, Ni, Sn, Au, Ag, Pt, Pd, and an alloy of one or more of these metals, compatible with the selected semiconductor technology, may be used. Each of the metallization layers defining contact areas and interconnect traces may comprise a single layer or a plurality of layers of conductive materials.

More generally, for example, the power semiconductor device may comprise one of: a power transistor, a power diode, and a combination of a power transistor and a power diode. The power semiconductor device may comprise one or a plurality of transistors, one or a plurality of diodes, a combination of at least one transistor and at least one diode. For example, the power semiconductor device may comprise a plurality of power transistor switches configured as a half-bridge, full-bridge, or other switch topology. The power transistor switches may be integrated on a single die, or configured by embedding multiple die in an embedded die package. A power semiconductor device such as a transistor device or power diode device, or power switching device, may comprise other components, e.g. integrated driver and/or control circuitry, sensors, and/or other active or passive components.

For example, where the power semiconductor switching device comprises at least high voltage, high current lateral power transistor, such as a GaN HEMT, a SiC MOSFET or a Si IGBT rated for high voltage operation at an elevated temperature, an additional layer of dielectric isolates interconnect areas, e.g. source and drain contact areas, in regions subject to high electric field during operation. The power semiconductor device may be power diode, such as a GaN, SiC or Si diode. The die may comprise other components, e.g. driver and/or control circuitry integrated with the power semiconductor device, or the power semiconductor device may be co-packaged with other components embedded in the package. Where the power semiconductor device comprises a plurality of power transistors, these may be configured as a half-bridge, full-bridge, or other switching topologies.

The embedded die package may be configured for a die comprising a power semiconductor device which is e.g. a lateral GaN power transistor, or a SiC MOSFET or a Si IGBT, or a diode. For example, the power semiconductor transistor may be a high voltage, high current lateral GaN HEMT rated for operation at ≥100V or ≥600V and for a current of tens of Amps to hundreds of Amps, and rated for operation at a temperature ≥75 C or ≥100 C.

In the forgoing description, any references to color elements in the drawings refer to the color version of the drawings that were submitted as non-black and white line drawings, and stored for access as supplemental material in the USPTO SCORE database.

Although embodiments of the invention have been described and illustrated in detail, it is to be clearly understood that the same is by way of illustration and example only and not to be taken by way of limitation, the scope of the present invention being limited only by the appended claims.

1. An embedded die package comprising a laminated body and a die comprising a power semiconductor device, the die being embedded within the laminated body, wherein:
the laminated body comprises comprising a layer stack of a plurality of dielectric layers and electrically conductive layers;
a first electrically conductive layer comprising a leadframe defining contact pads;
the die being mounted on the leadframe;
electrical connections between contact pads of the die, contact pads the leadframe and any other electrically conductive layers comprise electrically conductive vias extending through the dielectric layers;
wherein edges of the leadframe are structured provide vertical and lateral interlocking of the leadframe and surrounding dielectric layers.

2. The embedded die package of claim 1, where said edges of the leadframe comprises lateral scallops and a vertical undercut.

3. The embedded die package of claim 1, wherein edges of the leadframe are beveled.

4. The embedded die package of claim 1, wherein the dielectric layers comprise a glass fiber filled epoxy composite resin, and the lateral scallops are configured for stress relief of glass fibers within the resin.

5. The embedded die package of claim 1, meeting requirements for MSL Level 1 Qualification.

6. An embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a thermal pad, the thermal contact area of the die being in thermal contact with the thermal pad of the leadframe;
a dielectric core comprising at least a first dielectric build-up layer embedding the die and at least top and side surfaces of the leadframe;
a second conductive layer;
the second conductive layer being patterned to define interconnect areas;
the interconnect areas of the second conductive layer being connected by electrically conductive vias to respective electrical contact areas of the power semiconductor device and electrical contact areas of the leadframe; and
wherein edges of the leadframe are structured provide vertical and lateral interlocking of the leadframe and the at least first dielectric buildup layer embedding the at least top and side surfaces the leadframe.

7. An embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a primary thermal pad, the thermal contact area of the die being in thermal contact with the primary thermal pad of the leadframe;
a first dielectric build-up layer embedding the die and the leadframe;
a second conductive layer on the first dielectric build-up layer;
the second conductive layer being patterned to define interconnect areas;
the interconnect areas of the second conductive layer being connected by electrically conductive vias to respective electrical contact areas of the power semiconductor device and electrical contact areas of the leadframe; and
a second dielectric build-up layer on the second conductive layer;
a third conductive layer on the second dielectric build-up layer defining external electrical contact areas;
the external electrical contact areas of the third conductive layer being connected by electrically conductive vias to respective electrical internconnect areas of the second conductive layer; and
wherein edges of the leadframe are structured to provide lateral and vertical interlocking of at least the first dielectric buildup layer embedding the leadframe.

8. The embedded die package of claim 7, comprising a fourth conductive layer underlying the first conductive layer and separated therefrom by another dielectric build-up layer, the fourth conductive layer forming an external thermal pad which is in thermal contact with the primary thermal pad of the first conductive layer.

9. The embedded die package of claim 7, wherein thermally conductive vias provide said thermal contact between the first thermal pad and the external thermal pad.

10. The embedded die package of claim 7, wherein the power semiconductor device comprises a lateral power transistor, wherein said electrical contact areas of the power semiconductor device comprise electrical contact areas for a source, drain and gate of the lateral power transistor on the bottom-side of the package.

11. The embedded die package of claim 7, wherein vias comprising electrically conductive and thermally conductive material provide electrical connection and thermal contact between the first thermal pad and the source.

12. The embedded die package of claim 7, meeting requirements for MSL Level 1 qualification.

13. An embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a core comprising at least one dielectric layer which embeds the die;
a first dielectric build-up layer on a first side of the core;
a first conductive layer on the first dielectric build-up layer;
the first conductive layer comprising a leadframe, the leadframe being patterned to define a primary thermal pad and electrical interconnect areas, the thermal contact area of the die being in thermal contact with the primary thermal pad;
a second dielectric build-up layer on a second side of the core,
a second conductive layer on the second dielectric build-up layer,
the second conductive layer being patterned to define electrical contact areas, the interconnect areas of the first conductive layer being connected by electrically conductive vias to respective electrical contact areas of the power semiconductor device and respective electrical contact areas of the first conductive layer;
a third dielectric build-up layer on the first conductive layer;
a third conductive layer on the third dielectric build up layer;
the third conductive layer being patterned to define a secondary thermal pad;
wherein the primary and secondary thermal pads providing for dual-side cooling; and
wherein edges of the leadframe are structured to provide lateral and vertical interlocking of at least the first dielectric buildup layer embedding the leadframe.

14. The embedded die package of claim 13, wherein thermal vias provide for said thermal contact between the first thermal pad and the thermal contact on the back-side of the die.

15. The embedded die package of claim 13, comprising a fourth conductive layer underlying the first conductive layer and separated therefrom by another dielectric build-up layer, the fourth conductive layer forming an external thermal pad which is in thermal contact with the first thermal pad of the first conductive layer.

16. The embedded die package of claim 15, wherein thermally conductive vias provide said thermal contact between the first thermal pad and the external thermal pad.

17. The embedded die package of claim 13, wherein the power semiconductor device comprises a lateral power transistor, wherein said electrical contact areas of the power semiconductor device comprise electrical contact areas for a source, drain and gate of the lateral power transistor on the bottom-side of the package, and wherein the first thermal pad and the second thermal pad are internally connected to the source.

18. The embedded die package of claim 13, wherein vias comprising electrically conductive and thermally conductive material provide electrical connection and thermal contact between the first thermal pad and the source, and between the second thermal pad and the source.

19. The embedded die package of claim 13, meeting requirements for MSL Level 1 Qualification.
